(19) United States
(12) Patent Application Publication
(10) Pub. No.: US 2026/0198183 A1
(43) Pub. Date: Jul. 9, 2026

(54) DISPLAY PANEL AND DISPLAY DEVICE

(71) Applicant: HKC CORPORATION LIMITED, Shenzhen (CN)

(72) Inventors: Qin LIANG, Shenzhen (CN); Zhisheng XIE, Shenzhen (CN); Yangling TANG, Shenzhen (CN); Xiufeng ZHOU, Shenzhen (CN); Haijiang YUAN, Shenzhen (CN)

(21) Appl. No.: 19/426,058

(22) Filed: Dec. 19, 2025

(30) Foreign Application Priority Data
Jan. 7, 2025 (CN) 202510024359.0

(51) Int. Cl. H10K 59/122; H10K 59/80

(52) U.S. Cl. CPC H10K 59/122; H10K 59/873; H10K 59/8792

(57) ABSTRACT

A display panel and display device are disclosed. The display panel includes a substrate, a pixel-defining layer, a plurality of display sub-pixels, a plurality of anti-peeping sub-pixels, an encapsulation layer, a plurality of light-shielding layers, and a plurality of light-scattering structures. The plurality of anti-peeping sub-pixels are disposed in the non-opening area, with at least one anti-peeping sub-pixel provided within a pixel; each anti-peeping sub-pixels is separated from each display sub-pixel by the pixel-defining layer; the plurality of light-shielding layers are disposed on the plurality of anti-peeping sub-pixels, and are arranged in one-to-one correspondence with the anti-peeping sub-pixels respectively; each of the plurality of light-scattering structures is disposed between each of the plurality of anti-peeping sub-pixels and each of the plurality of light-shielding layers.

### CROSS-REFERENCE TO RELATED APPLICATIONS

The present disclosure claims the priority and benefit of Chinese patent application number 2025100243590, titled "Display Panel and Display Device" and filed on January 7, 2025 with China National Intellectual Property Administration, the entire contents of which are incorporated herein by reference.

### TECHNICAL FIELD

The present disclosure relates to the technical field of display, and more particularly relates to a display panel and a display device.

### BACKGROUND

The description provided in this section is intended for the mere purpose of providing background information related to the present disclosure but does not necessarily constitute related art.

Currently, with the gradual maturity of Organic Light-Emitting Diode (OLED) organic light-emitting display technology, and as a self-emissive display technology, its applications in products have become increasingly widespread. With the growing emphasis on personal anti-peeping in modern society, the anti-peeping function of display panels has also become an essential feature of products. Therefore, Organic Light-Emitting Diode (OLED) anti-peeping technology has recently become a hot topic of discussion.

In an anti-peeping technology for adding anti-peeping pixels, anti-peeping sub-pixels may be disposed between two adjacent display sub-pixels. The anti-peeping light emitted by the anti-peeping sub-pixels disrupts the display effect at a large viewing angle, thereby achieving the anti-peeping effect. However, currently, the utilization rate of the anti-peeping light is relatively low, resulting in the problem of poor anti-peeping effect.

### SUMMARY

An objective of the present disclosure is to provide a display panel and a display device, by adding a light scattering structure in the area where the anti-peeping sub-pixels are located, the utilization rate of the anti-peeping light at a lateral viewing angle may be improved without changing the film layer structure, thereby enhancing the anti-peeping effect of the display panel.

Disclosed in the present disclosure is a display panel, the display panel includes a plurality of opening areas and a non-opening area, and further includes a substrate, a pixel-defining layer, a plurality of display sub-pixels, a plurality of anti-peeping sub-pixels, an encapsulation layer, a plurality of light-shielding layers, and a plurality of light scattering structures, the pixel-defining layer is disposed on the substrate and located in the non-opening area, the plurality of display sub-pixels are disposed in one-to-one correspondence with the plurality of opening areas respectively, and two adjacent display sub-pixels are separated by the pixel-defining layer, the plurality of anti-peeping sub-pixels are disposed in the non-opening area, with at least one anti-peeping sub-pixel provided within a pixel; and each of the plurality of anti-peeping sub-pixels is separated from each of the plurality of display sub-pixels by the pixel-defining layer; the encapsulation layer is disposed over the pixel-defining layer, the plurality of display sub-pixels, and the plurality of anti-peeping sub-pixels, and is configured to seal the display sub-pixels and the anti-peeping sub-pixels; the plurality of light-shielding layers are disposed on the plurality of anti-peeping sub-pixels, and are arranged in one-to-one correspondence with the anti-peeping sub-pixels respectively, configured to block the light emitted perpendicularly to the substrate from the anti-peeping sub-pixels; each of the plurality of light scattering structures is disposed between each of the plurality of anti-peeping sub-pixels and each of the plurality of light-shielding layers, and are configured to scatter part of the anti-peeping light emitted from the anti-peeping sub-pixels to the light-shielding layers, such that the scattered light exits from each of the plurality of opening areas.

Embodiments of the present disclosure further disclose a display panel, the display panel includes a driving circuit and a display panel, the driving circuit is configured to drive the display panel to perform the display operation; the display panel includes a plurality of opening areas and a non-opening area, and further includes a substrate, a pixel-defining layer, a plurality of display sub-pixels, a plurality of anti-peeping sub-pixels, an encapsulation layer, a plurality of light-shielding layers, and a plurality of light scattering structures, the pixel-defining layer is disposed on the substrate and located in the non-opening area, the plurality of display sub-pixels are disposed in one-to-one correspondence with the plurality of opening areas respectively, and two adjacent display sub-pixels are separated by the pixel-defining layer, the plurality of anti-peeping sub-pixels are disposed in the non-opening area, with at least one anti-peeping sub-pixel provided within a pixel; and each of the plurality of anti-peeping sub-pixel is separated from each of the plurality of display sub-pixel by the pixel-defining layer; the encapsulation layer is disposed over the pixel-defining layer, the plurality of display sub-pixels, and the plurality of anti-peeping sub-pixels, and is configured to seal the display sub-pixels and the anti-peeping sub-pixels; the plurality of light-shielding layers are disposed on the plurality of anti-peeping sub-pixels, and are arranged in one-to-one correspondence with the anti-peeping sub-pixels respectively, configured to block the light emitted perpendicularly to the substrate from the anti-peeping sub-pixels; each of the plurality of light scattering structures is between each of the plurality of anti-peeping sub-pixels and each of the plurality of light-shielding layers, and are configured to scatter part of the anti-peeping light emitted from the anti-peeping sub-pixels to the light-shielding layers, such that the scattered light exits from each of the plurality of opening areas.

### BRIEF DESCRIPTION OF DRAWINGS

The included drawings are provided for further understanding of embodiments of the present disclosure, constitute a part of the specification, illustrate embodiments of the present disclosure, and together with the text description, explain principles of the present disclosure. Obviously, the drawings in the following description are merely some embodiments of the present disclosure. For those of ordinary skill in the art, other drawings may be obtained based on these drawings without creative labor. In the drawings:

FIG. 1 is a top view of the display panel according to a first embodiment of the present disclosure.

FIG. 2 is a cross-sectional view of the display panel according to the first embodiment of the present disclosure.

FIG. 3 is a schematic diagram of the light emission intensity of the anti-peeping sub-pixels without light scattering structures and the display sub-pixels at different angles according to the present disclosure.

FIG. 4 is a schematic diagram of the display panel according to a second embodiment of the present disclosure.

FIG. 5 is a schematic diagram of the pixel arrangement according to the second embodiment of the present disclosure.

FIG. 6 is a schematic diagram of a first display panel according to a third embodiment of the present disclosure.

FIG. 7 is a schematic diagram of a second type of display panel according to the third embodiment of the present disclosure.

FIG. 8 is a schematic diagram of a first type of display panel according to a fourth embodiment of the present disclosure.

FIG. 9 is a schematic diagram of a second type of display panel according to the fourth embodiment of the present disclosure.

FIG. 10 is a schematic diagram of the display device according to the present disclosure.

### DETAILED DESCRIPTION OF EMBODIMENTS

It should be understood that the terminology, specific structures, and functional details disclosed herein are merely used to describe specific embodiments and are illustrative. However, the present disclosure may be implemented through many alternative forms and should not be construed as limited solely to the embodiments described herein.

In the description of the present disclosure, terms such as "first" and "second" are used solely for descriptive purposes and should not be interpreted as indicating relative importance or implicitly specifying the number of technical features indicated. Thus, unless otherwise specified, features qualified by "first" or "second" may explicitly or implicitly include one or more such features. "A plurality of" means two or more. The term "comprise" and any variations thereof indicate non-exclusive inclusion, such that there may exist or be added one or more other features, integers, steps, operations, elements, components, and/or combinations thereof.

Additionally, directional or positional terms such as "center," "transversal," "upper," "lower," "left," "right," "vertical," "horizontal," "top," "bottom," "inside," or "outside" are described based on orientations or relative positional relationships shown in the accompanying drawings, which are used for simplified description to facilitate understanding of the present application and do not imply that the devices or elements described should have specific orientations or be constructed or operated in specific orientations. These terms should not be construed as limiting the present disclosure.

Additionally, unless otherwise explicitly specified and limited, the term "mount," "link," "connect," and the like should be understood in a broad sense, for example, as a fixed connection, as a detachable connection, as an integral connection, as a mechanical connection, as an electrical connection, as a direct connection, as an indirect connection through an intermediate medium, or as a connection within two elements. For those skilled in the art, the specific meaning of the above terms in the context of the present disclosure may be understood according to the specific situation.

The present disclosure is described below in detail with reference to the accompanying drawings and optional embodiments.

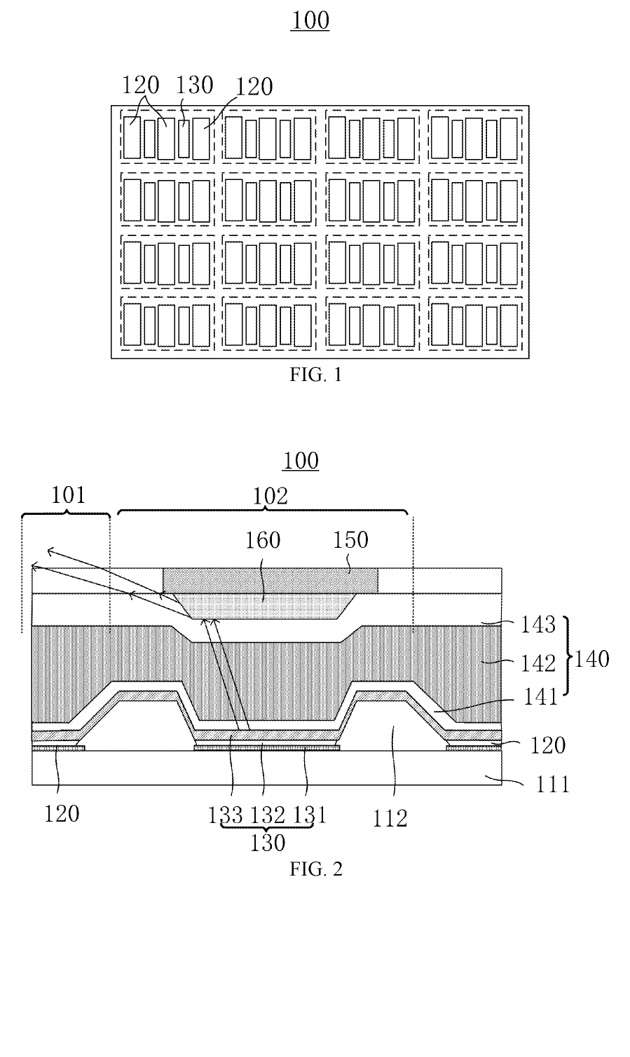

FIG. 1 is a top plan view of the display panel according to the first embodiment of the present disclosure, and FIG. 2 is a cross-sectional view of the display panel according to the first embodiment of the present disclosure. As shown in FIGS. 1 to 2. Disclosed in the present disclosure is a display panel 100, which includes a plurality of opening areas 101 and a non-opening area 102, the display panel 100 further includes a substrate 111, a pixel-defining layer 112, a plurality of display sub-pixels 120, a plurality of anti-peeping sub-pixels 130, an encapsulation layer 140, a plurality of light-shielding layer 150, and a plurality of light-scattering structure 160; the pixel-defining layer 112 is disposed on the substrate 111 and located within the non-opening area 102; the plurality of display sub-pixels 120 are disposed in one-to-one correspondence with the plurality of opening areas 101 respectively, and two adjacent display sub-pixels are separated by the pixel-defining layer 112; the anti-peeping sub-pixels 130 are disposed in the non-opening area 102, with at least one anti-peeping sub-pixel 130 provided within a per pixel. And each of the plurality of anti-peeping sub-pixels 130 is separated from each of the plurality of display sub-pixels 120 by the pixel-defining layer 112; the encapsulation layer 140 is disposed over the pixel-defining layer 112, the plurality of display sub-pixels 120, and the plurality of anti-peeping sub-pixels 130, and is configured to seal the display sub-pixels 120 and the anti-peeping sub-pixels 130; the plurality of light-shielding layers 150 are disposed on the plurality of anti-peeping sub-pixels 130, and are arranged in one-to-one correspondence with the anti-peeping sub-pixels respectively, configured to block light emitted perpendicularly to the substrate from the anti-peeping sub-pixels; each of the plurality of light-scattering structures 160 is disposed between each of the plurality of anti-peeping sub-pixels 130 and each of the plurality of light-shielding layers 150, configured to scatter part of the anti-peeping light emitted from each of the plurality of anti-peeping sub-pixels 130 to each of the plurality of light-shielding layers 150 causing scattered light to be outwent from each of the plurality of opening areas 101.

According to the present disclosure adds a light-scattering structure 160 in the region where the anti-peeping sub-pixels 130 are located. Such that as much light as possible no longer exits perpendicularly to the substrate 111, thereby creating a divergent effect, when the anti-peeping sub-pixels 130 emit anti-peeping light, the light-scattering structure 160 scatters the anti-peeping light emitted by the anti-peeping sub-pixels 130. In such a case, most of the anti-peeping light emitted by the anti-peeping sub-pixels 130 is no longer blocked by the light-shielding layer 150, but instead may exit through the adjacent opening area 101. This enhances the quantity and intensity of anti-peeping light emitted from the anti-peeping sub-pixels 130 through the opening area 101, thereby improving the light utilization efficiency of the anti-peeping sub-pixels 130. In the present disclosure, by adding the light-scattering structure 160 without requiring additional improvements to other film layers, the problem of weak anti-peeping protection caused by insufficient anti-peeping light from the anti-peeping sub-pixels 130 is addressed at a relatively low cost.

In the embodiment, an interior of each of the plurality of light-scattering particles is provided with light scattering particles, and the light-scattering particles include inorganic particles, organic particles, or composite particles; the light-scattering particles are configured to alter the propagation direction of light, such that part of the anti-peeping light outwent from the anti-peeping sub-pixel 130 toward the light-shielding layer 150 is scattered and outwent through the opening area 101. The main body of the light-scattering structure 160 is formed of an organic material, and light-scattering particles are doped into the organic material to enable the light-scattering structure 160 to scatter light. It should be understood that the light-scattering particles are uniformly distributed within the organic material to achieve uniform light dispersion.

Specifically, the light-scattering particles include inorganic particles, organic particles, composite particles, or the like. Inorganic particles, such as titanium oxide, silicon oxide, zinc oxide, or a mixture of one or more thereof. The organic particles may be one or a mixture of silicone microspheres, polyacrylic acid series, polymethyl methacrylate (PMMA), or the like. The composite particles may be particles formed by mixing one or more inorganic particles and organic particles, the composite particles have a refracting effect on light, such that light is scattered after passing through the light-scattering structure 160.

Generally, the direction perpendicular to the substrate 111 is defined as the normal direction of the display panel 100. For a wide-angle display panel 100, the viewing angle is approximately 160 degrees, meaning the maximum angle between the emitted light and the normal direction of the display panel 100 may reach 80 degrees. For a typical display panel 100, the viewing angle is approximately 120 degrees, meaning the maximum angle between the emitted light and the normal direction may reach 60 degrees. For anti-peeping protection purposes, it is required that interference occurs when the angle between the emitted light and the normal direction of the display panel 100 exceeds 25 degrees. That is, the range where the angle between the emitted light and the normal direction of the display panel 100 is from 0 degrees to 25 degrees is defined as the normal viewing angle, while the range exceeding 25 degrees is defined as the anti-peeping viewing angle. Causing phenomena such as different gray scales and color mixing of the display sub-pixels in the anti-peeping viewing angle, it makes the display content unrecognizable in the anti-peeping viewing angle, thereby achieving the anti-peeping protection function, the light from the anti-peeping sub-pixels 130 is emitted at angles exceeding 25 degrees from the normal direction of the display panel 100. However, since most of the vertically emitted light from the anti-peeping sub-pixels 130 is blocked by the light-shielding layer 150, the light utilization efficiency in the anti-peeping viewing angle is low. It is worth noting that the above-mentioned light-shielding layer 150 needs to completely block the vertically emitted light from the anti-peeping sub-pixels 130. Therefore, the area of the light-shielding layer 150 is larger than the light-emitting area of the anti-peeping sub-pixels 130. However, the area of the light-shielding layer 150 may be reduced to be smaller than that of the non-opening area 102. That is, in the orthographic projection of the substrate 111, the projection of the light-shielding layer 150 falls within the projection of the pixel-defining layer 112. Thus, the aforementioned anti-peeping light may exit through the opening area 101 after refraction, or through the unobstructed areas of the light-shielding layer 150 within the non-opening area 102.

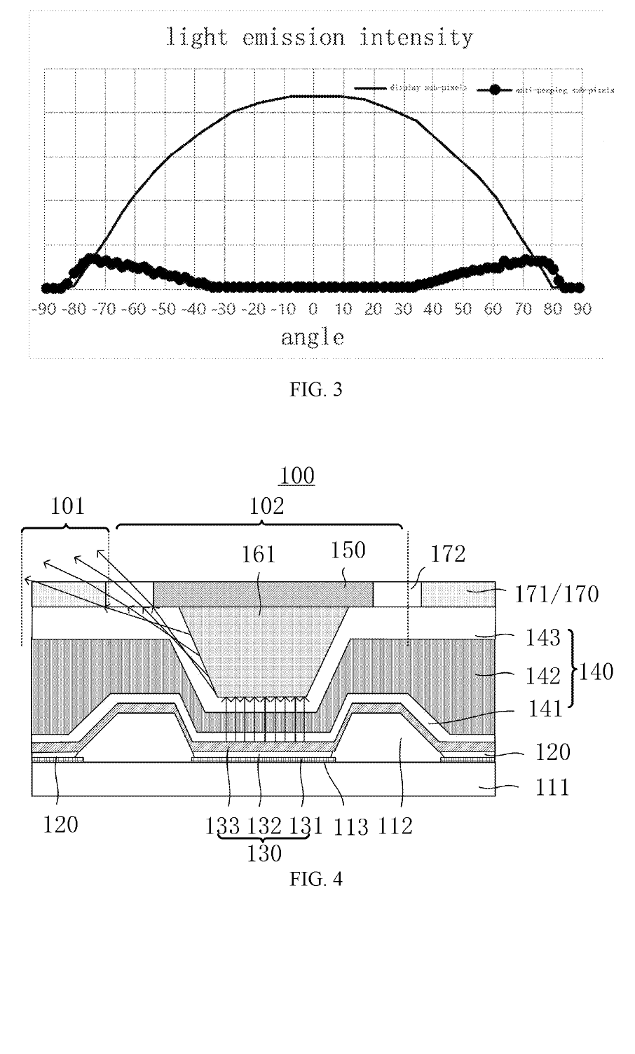

FIG. 3 is a schematic diagram of the light emission intensity of the anti-peeping sub-pixels without light scattering structures and the display sub-pixels at different angles according to the present disclosure. As shown in FIG. 3, the horizontal axis represents the angle between the emitted light from the anti-peeping sub-pixels 130 and display sub-pixels 120 and the normal direction of the display panel 100, while the vertical axis represents the intensity of the emitted light from the anti-peeping sub-pixels 130 and display sub-pixels 120 at that angle. At present, when both the anti-peeping sub-pixels 130 and the display sub-pixels 120 adopt the structure of light-emitting elements, they are respectively formed at the opening positions of the pixel-defining layer 112. Namely, the luminous efficiencies are comparable when the light-emitting layers of the anti-peeping sub-pixels 130 and the display sub-pixels 120 are both formed by simultaneous evaporation. As the angle between the emitted light from the anti-peeping sub-pixels 130 and display sub-pixels 120 and the normal direction of the display panel 100 gradually increases, the luminous intensity of the anti-peeping sub-pixels 130 also decreases gradually. Since this disclosure utilizes the light emitted by the anti-peeping sub-pixels 130 at the anti-peeping viewing angle, causing the problem of poor anti-peeping protection effect particularly when the angle between the emitted light from the anti-peeping sub-pixels 130 and display sub-pixels 120 and the normal direction of the display panel 100 is between 25 degrees and 45 degrees, the anti-peeping light is seriously insufficient.

Continuing to refer to FIG. 2, in one embodiment, each of the plurality of light-scattering structures 160 includes a first scattering structure 161. Each first scattering structure 161 is disposed in direct contact with each of the plurality of light-shielding layers 150, and disposed between each of the plurality of light-shielding layers 150 and the encapsulation layer 140.

In the present embodiment, the first scattering structure 161 is disposed below the light-shielding layer 150 and is in direct contact therewith. The main function of the first scattering structure 161 is to diverge light emitted from the anti-peeping sub-pixels 130 perpendicularly to the substrate 111 toward the light-shielding layer 150 or incident on the light-shielding layer 150 at other angles, such that the light is emitted in a divergent manner. In other words, due to the scattering effect of the first scattering structure 161, the light from the anti-peeping sub-pixels 130, upon entering the first scattering structure 161, causes the first scattering structure 161 to form a new anti-peeping light source. The new light source exhibits a light-scattering effect and is positioned closest to the light-shielding layer 150. It is equivalent to shifting the position of the anti-peeping light source from below the encapsulation layer 140 to below the light-shielding layer 150 through the light-scattering effect of the first scattering structure 161, thereby achieving optional light shielding and anti-peeping protection effects. Moreover, the present embodiment may direct more light from the first scattering structure 161 into the anti-peeping viewing angle, thereby enhancing the anti-peeping protection effect. By adding the light-scattering structure within the encapsulation layer 140, the disclosure strengthens the anti-peeping light of the anti-peeping sub-pixels 130 within the 25 degrees and 45 degrees anti-peeping viewing angle.

Under an orthogonal projection of the substrate 111, a projection of each first light-scattering structure 161 falls within a projection of each of the plurality of light-shielding layers 150.

Generally, considering the light leakage issue of the anti-peeping sub-pixels 130, the area of the light-shielding layer 150 needs to cover the anti-peeping sub-pixels 130, so as to block the vertically emitted light from the anti-peeping sub-pixels 130 and avoid interfering with the light in the normal viewing angle. Therefore, in the orthographic projection of the substrate 111, the area of the anti-peeping sub-pixels 130 should be smaller than that of the light-shielding layer 150, and the area of the first scattering structure 161 should also be smaller than that of the light-shielding layer 150.

Continuing to refer to FIG. 2, in the solution, the cross-sectional shape of each of the plurality of first scattering structures 161 is an inverted trapezoid. When forming the first scattering structure 161, a groove is first formed on the encapsulation layer 140, and the groove is configured to accommodate the first scattering structure 161.

Specifically, the encapsulation layer 140 includes a first inorganic layer 141, an organic layer 142, and a second inorganic layer 143. The first inorganic layer 141 is disposed to cover the anti-peeping sub-pixels 130 and the display sub-pixels 120. The organic layer 142 is disposed between the first inorganic layer 141 and the second inorganic layer 143. The first inorganic layer 141 is arranged at the bottommost part of the encapsulation layer 140, while the second inorganic layer 143 is arranged at the topmost part. The stacking of inorganic and organic materials achieves the water-oxygen sealing of pixels. Generally, the thickness of the organic layer 142 is greater than that of the first inorganic layer 141 and the second inorganic layer 143.

In the present embodiment, each of the plurality of first scattering structures 161 is disposed on the second inorganic layer 143, and the thickness of the first scattering structure 161 is slightly greater than that of the second inorganic layer 143. A plurality of grooves are formed in the organic layer 142, and after the second inorganic layer 143 covers the plurality of grooves, another groove is formed on the second inorganic layer 143 at a position corresponding to the aforementioned each of the plurality of grooves. Each first scattering structure 161 is accommodated within each of the plurality of grooves formed on the second inorganic layer 143. Specifically, the thickness of the first scattering structure 161 may be improved by controlling the depth of the groove formed in the organic layer 142. It should be understood that the groove is designed only for the area corresponding to the anti-peeping sub-pixels 130.

In one or more embodiments, the cross-sectional shape of each of the plurality of first scattering structures 161 may also be an inverted trapezoid, semicircle, semi-ellipse, triangle, or rectangle. The first scattering structure 161 with different cross-sectional shapes exhibits varying intensities of light modulation effects. For example, the first scattering structure 161 with an arc surface, such as a semicircle or semi-ellipse, is more conducive to light emission.

FIG. 4 is a schematic diagram of the display panel according to the second embodiment of the present disclosure, as shown in FIG. 4, in the present embodiment, by forming a groove with a relatively deep thickness in the organic layer 142, the thickness of the first scattering structure 161 in the direction perpendicular to the substrate 111 is made greater than the width in the direction parallel to the substrate 111. In such a case, the cross-sectional shape of each of the plurality of first scattering structures 161 is a rectangle or trapezoid. When it is a rectangle, it is a vertically oriented rectangle, meaning the length direction of the rectangle is perpendicular to the substrate 111. When it is a trapezoid, the height of the trapezoid is greater than half the sum of the upper and the lower base. Specifically, in the present embodiment, the key approach is to increase the thickness of the first scattering structure 161, thereby reducing the width of the first scattering structure 161, and reducing the first scattering structure 161's width in turn allows for further reduction in the width of the light-shielding layer 150.

Generally, in solutions that enhance anti-peeping by adding anti-peeping sub-pixels 130, openings need to be formed in the regions where the anti-peeping sub-pixels 130 are located. These openings are often designed to be the same as those of the normal display sub-pixels 120, enabling the anti-peeping sub-pixels 130 and display sub-pixels 120 to be formed simultaneously. This approach, however, leads to the problem that the anti-peeping sub-pixels 130 occupy the area of the display sub-pixels 120. For example, a pixel typically includes three display sub-pixels 120, each accounting for approximately one-third of the pixel area. When the area of a pixel remains unchanged, adding an anti-peeping sub-pixel 130 would cause the display sub-pixels 120 to occupy only one-fourth of the pixel area, with the anti-peeping sub-pixel 130 also occupying one-fourth thereof. It results in the anti-peeping sub-pixel 130 occupying the area of the display sub-pixels 120. Specifically, the reduction in the size of the display sub-pixels 120 leads to display issues when the pixel area is fixed.

In the present embodiment, the area of each of the plurality of anti-peeping sub-pixels 130 is smaller than each of the plurality of display sub-pixels 120. By reducing the area of the anti-peeping sub-pixel 130, a smaller anti-peeping light-emitting element may be disposed in the non-opening area 102. The first scattering structure 161 is configured to fully utilize the anti-peeping light emitted by the anti-peeping light-emitting element, thereby enhancing the anti-peeping capability within the anti-peeping viewing angle without occupying the area of the display sub-pixels 120.

It is worth noting that the corresponding anti-peeping light becomes weaker and the anti-peeping protection capability decreases when the area of the anti-peeping sub-pixel 130 is reduced. However, in the present embodiment, by providing the first scattering structure 161, when the thickness of the first scattering structure 161 reaches at least half of the distance between the light-shielding layer 150 and the anti-peeping sub-pixel 130, the anti-peeping light from the anti-peeping sub-pixel 130 may undergo refraction through the first scattering structure 161. As a result, within the anti-peeping viewing angle, most of the anti-peeping light may be received, thereby enhancing the anti-peeping light even when the area of the anti-peeping sub-pixel 130 is reduced.

In one or more embodiments, the pixel-defining layer 112 is further provided with a plurality of anti-peeping openings 113 to accommodate the anti-peeping sub-pixels 130, with each anti-peeping sub-pixel disposed in one-to-one correspondence with each of the plurality of anti-peeping openings. Each of the plurality of anti-peeping sub-pixels 130 generally includes an anti-peeping light-emitting element, and each anti-peeping light-emitting element includes a bottom electrode 131, a light-emitting layer 132, a top electrode 133, etc. Each of the plurality of anti-peeping light-emitting elements is disposed within each of the plurality of anti-peeping openings 113. Generally, the thickness of the pixel-defining layer 112 is greater than that of the anti-peeping light-emitting element. Therefore, after the anti-peeping light-emitting element is disposed within the anti-peeping opening 113, the surface of the anti-peeping light-emitting element distal from the substrate 111 is also lower than the surface of the pixel-defining layer 112 distal from the substrate 111. After forming the anti-peeping light-emitting element, the first inorganic layer 141 of the encapsulation layer 140 is configured to protect the anti-peeping light-emitting element, preventing water and oxygen intrusion from causing failure of the anti-peeping light-emitting element.

Notably, each of the plurality of display sub-pixels 120 in the present disclosure generally includes a display light-emitting element, each of the plurality of display light-emitting elements may be divided into red light-emitting elements, green light-emitting elements, and blue light-emitting elements. The structure of each of the plurality of display light-emitting elements is substantially the same as each of the plurality of anti-peeping light-emitting elements, with the only difference lying in the materials of the light-emitting layer 132. That is, different light-emitting layer materials are required when the light-emitting elements need to emit light of different colors. For example, a red light-emitting element requires a red light-emitting layer material, a green light-emitting element requires a green light-emitting layer material, and a blue light-emitting element requires a blue light-emitting layer material. For anti-peeping light-emitting elements, one or more of red, green, or blue light-emitting layer materials may be configured to achieve the emission of corresponding color light.

For each of the first light scattering structures 161, a thickness is maximized such that a height of a surface of each of the first light scattering structure 161 proximate to each of the plurality of anti-peeping sub-pixels 130 is lower than that of a surface of the pixel-defining layer 112 proximate to each of the plurality of light-shielding layers 150. The configuration ensures that anti-peeping light emitted by the anti-peeping light-emitting element may enter the first light scattering structure 161 to the greatest extent possible, where the light is refracted by the first light scattering structure 161 and directed outwards.

In one or more embodiments, quantum dots may be further incorporated into the first light scattering structure 161. Quantum dot materials may be configured to replace the aforementioned scattering particles or co-act with the scattering particles, such that the first light scattering structure 161, when excited by light emitted from the anti-peeping sub-pixel 130, becomes a new anti-peeping light source. Using the first light scattering structure 161 disposed below the light-shielding layer 150 as a new anti-peeping light source makes it closer to the light-shielding layer 150 than the anti-peeping sub-pixel 130 disposed in the film layer of the pixel-defining layer 112. In the anti-peeping viewing angle, the configuration allows the human eye to observe more anti-peeping light, thereby achieving an optional anti-peeping effect.

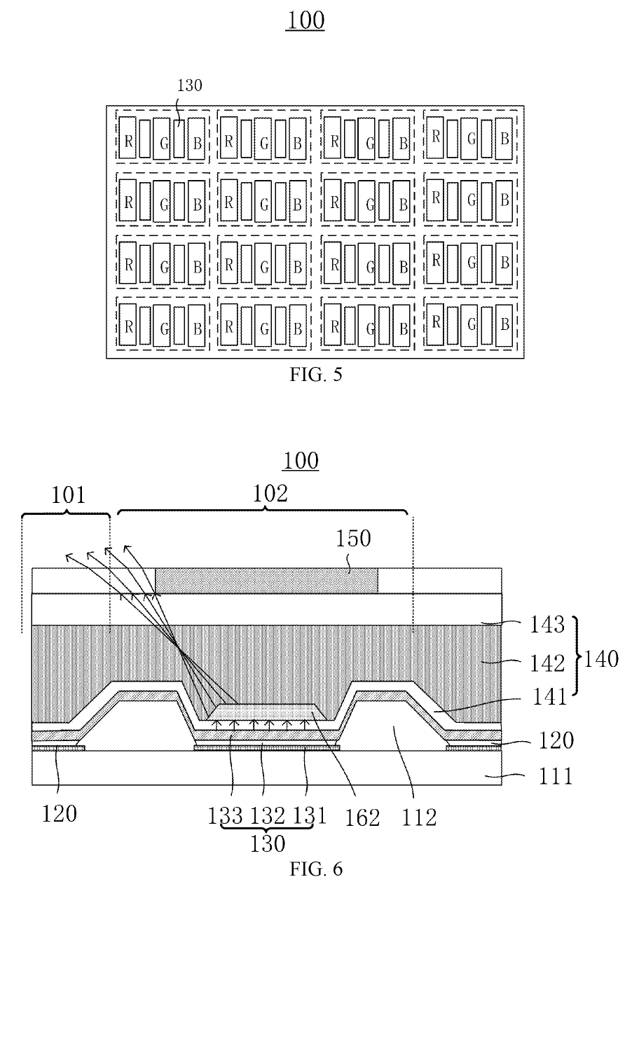

FIG. 5 is a schematic diagram of the pixel arrangement according to the second embodiment of the present disclosure, as shown in FIG. 5, the display panel 100 includes a plurality of pixels, each of the plurality of pixels including a plurality of display sub-pixels 120 and at least one anti-peeping sub-pixel 130. The anti-peeping sub-pixel 130 is disposed between two adjacent display sub-pixels 120, and the display sub-pixels 120 are classified into red sub-pixels R, green sub-pixels G, and blue sub-pixels B. For example, when the display sub-pixels 120 are arranged in a stripe pattern (RGB Stripe), the anti-peeping sub-pixel 130 may be disposed between two display sub-pixels 120 of different colors within one pixel.

Specifically, the present embodiment is applicable to an Organic Light-Emitting Diode (OLED) display panel 100 employing Color Filter on Encapsulation (COE) technology. The display panel 100 further includes a color filter layer 170, the color filter layer 170 includes a plurality of color filter portions 171 and a plurality of black matrixes. The plurality of color filter portions 171 are arranged in one-to-one correspondence with the plurality of display sub-pixels 120, and the plurality of black matrixes are disposed in the same layer as the plurality of color filter portions 171. Adjacent two of the color filter portions 171 are separated by one of the black matrixes. Generally, the black matrix provided in the color filter layer 170 may serve as the light-shielding layer 150 in the embodiment. That is, the black matrix is disposed corresponding to the non-opening areas 102, and the light-shielding layer 150 in the embodiment is replaced by the black matrix.

Specifically, when the display panel 100 is a Color Filter on Encapsulation (COE) technology-based display panel 100 in accordance with the previous embodiment, the quantum dot material at the position of the anti-peeping sub-pixel 130 may be selected according to the setting position of the anti-peeping sub-pixel 130. Generally, different quantum dot materials may emit light of specific colors when excited by the light from the anti-peeping sub-pixel 130, thereby achieving different color emissions. Therefore, in the first light scattering structure 161 between the red sub-pixel and the green sub-pixel, one or both of red quantum dots or green quantum dots may be added; in the first light scattering structure 161 between the red sub-pixel and the blue sub-pixel, one or both of red quantum dots or blue quantum dots may be added; and in the first light scattering structure 161 between the green sub-pixel and the blue sub-pixel, one or both of green quantum dots or blue quantum dots may be added. The above consideration is that the color filter portions 171 of different colors each have a filtering effect on light of specific colors when the color filter layer 170 is provided. For example, if blue quantum dot material is added to the first light scattering structure 161 between the red sub-pixel and the green sub-pixel, when the blue quantum dot material emits blue light, the blue light is completely absorbed by the red filter portion and the green filter portion, resulting in the inability of the anti-peeping light source to emit light and thus failing to achieve the anti-peeping effect.

In one or more embodiments, a light-transmitting portion 172 may be disposed between each of the plurality of light-shielding layers 150 and each of the plurality of color filter portions 171 to avoid interference of the color filter portion 171 with anti-peeping light. Specifically, the color filter layer 170 includes a plurality of color filter portions 171 and a plurality of light-transmitting portions 172. The plurality of color filter portions 171 are disposed in one-to-one correspondence with the plurality of display sub-pixels 120, and the plurality of light-shielding layer 150 and the plurality of light-transmitting portions 172 are disposed on the same layer as the color filter portions 171. A light-transmitting portion 172 is disposed between each adjacent pair of the color filter portion 171 and the light-shielding layer 150.

In the present embodiment, due to the reduction in size of the anti-peeping sub-pixel 130, the area of the light-shielding layer 150 may be further reduced. A light-transmitting portion 172 is disposed between the light-shielding layer 150 and the color filter portion 171, which may be formed of an organic material with high light transmittance. It allows the light scattered by the first light scattering structure 161 to exit from the anti-peeping viewing angle, achieving an optional anti-peeping effect. It may be understood that since the exterior of the light-transmitting portion 172 or the color filter portion 171 is air, the refractive index of air is generally lower than that of the light-transmitting portion 172 or the color filter portion 171, and the refractive index of the second inorganic layer 143 is higher than that of the light-transmitting portion 172 and the color filter portion 171, thereby enabling further refraction of light.

FIG. 6 is a schematic diagram of a first type of display panel according to the third embodiment of the present disclosure, and FIG. 7 is a schematic diagram of a second type of display panel according to the third embodiment of the present disclosure. As shown in FIGS. 6 to 7, the present disclosure also discloses another display panel 100, where each of the plurality of light-scattering structures 160 in the display panel 100 further includes a second light scattering structure 162, and each of the plurality of second light scattering structures 162 is disposed between the first inorganic layer 141 and the organic layer 142.

In the present embodiment, the second light scattering structure 162 is disposed within the encapsulation layer 140, utilizing the space between the first inorganic layer 141 and the organic encapsulation layer 140 to accommodate the second light scattering structure 162. The second light scattering structure 162 is generally also made of organic materials, and it has minimal impact on the encapsulation layer 140 when the organic layer 142 in the encapsulation layer 140 is relatively thick.

In an orthographic projection of the substrate 111, each of the second light scattering structures 162 falls within the projection range of each of the light-shielding layer 150.

Considering that the second light scattering structure 162 protrudes beyond the light-shielding layer 150, it is prone to affecting frontally emitted light, thus influencing the display effect at a normal viewing angle. Especially for the solution where the light-transmitting portion 172 is disposed between the light-shielding layer 150 and the color filter portion 171, it is necessary to set the width of the second light scattering structure 162 to be small thereby achieving that the second light scattering structure 162 is visible at an anti-peeping viewing angle while being imperceptible at a normal viewing angle.

The pixel-defining layer 112 is further provided with a plurality of anti-peeping openings 113 configured to accommodate the anti-peeping sub-pixels 130, with each anti-peeping sub-pixel 130 is disposed in one-to-one correspondence with each of the plurality of anti-peeping openings 113.

The arrangement of the second light scattering structure 162 is mainly to address the gradual weakening of the emitted light from the anti-peeping light-emitting element as the emission angle changes from a direction perpendicular to the substrate 111 to larger angles. By providing the second light scattering structure 162, the light emission angle of the anti-peeping light-emitting element may be modified, increasing the intensity of the emitted light in large-angle directions. This enhances the intensity of the light emitted by the anti-peeping sub-pixel 130 at the anti-peeping viewing angle.

In a case where each of the plurality of the light scattering structure 160 includes a first light scattering structure 161 and a second light scattering structure 162, a width of each of the second light scattering structure 162 is less than that of each of the first light scattering structure 161. A region of organic encapsulation layer 140 corresponding to the anti-peeping sub-pixels is provided with a plurality of grooves, and each first light scattering structure 161 is correspondingly disposed within each of the plurality of grooves..

In one embodiment, the second light scattering structure 162 may be used in combination with the first light scattering structure 161 or used alone. When used in combination with the first light scattering structure 161, the scattering ability for the anti-peeping light of the anti-peeping sub-pixel 130 is enhanced.

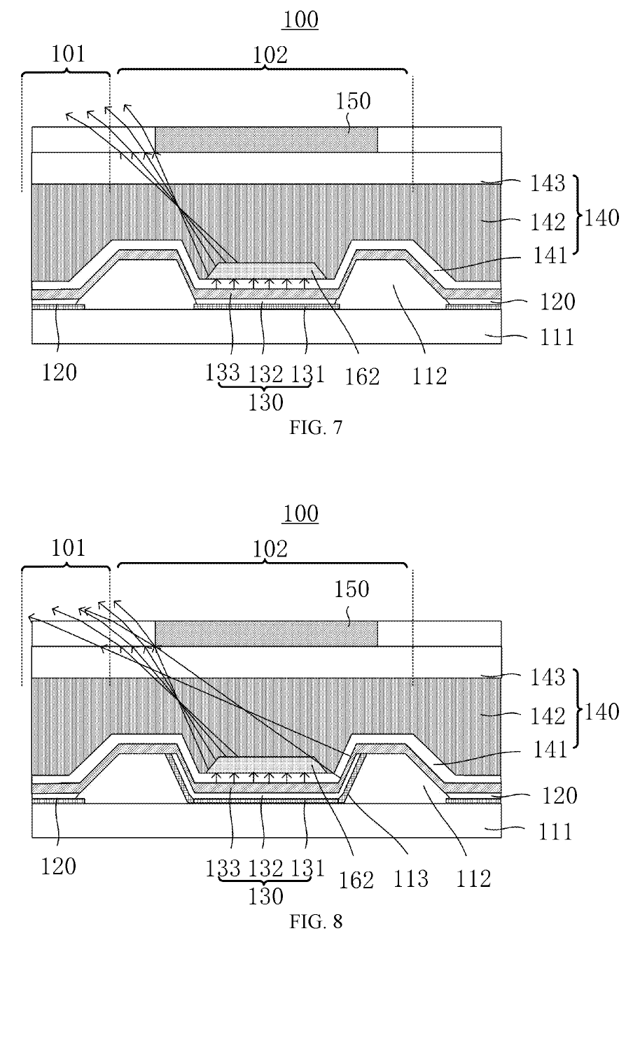

FIG. 8 is a schematic diagram of a first type of display panel according to the fourth embodiment of the present disclosure. As shown in FIG. 8, in the embodiment, in addition to adding the above-described light scattering structure 160, further improvements may be made to the anti-peeping light-emitting element.

In one or more embodiments, each of the plurality of anti-peeping sub-pixels 130 includes an anti-peeping light-emitting element. A sidewall of each of the plurality of anti-peeping openings 113 has a preset inclination angle to form an inclined surface. Each anti-peeping light-emitting element extends from a bottom of the corresponding anti-peeping opening 113 to a sidewall of the anti-peeping opening 113, the anti-peeping light outwent by each of the anti-peeping light-emitting elements in a region corresponding to the sidewall of each of the plurality of anti-peeping opening outgoes toward the plurality of opening areas 101 corresponding to the anti-peeping light-emitting elements.

In the solution, by disposing the bottom electrode 131, light-emitting layer 132, and top electrode 133 of the anti-peeping light-emitting element on the sidewall of each of the plurality of anti-peeping openings 113, the anti-peeping light-emitting element is enabled to emit light from the sidewall of the anti-peeping opening 113. That configuration enhances the light emission intensity of the anti-peeping light-emitting element at the anti-peeping viewing angle.

It may be understood that the anti-peeping light-emitting element does not require the same level of high emission brightness and brightness adjustability as the light-emitting element of the display sub-pixel 120, as the standards for the display sub-pixels 120 are relatively higher. The main function of the anti-peeping light-emitting element in the anti-peeping sub-pixel 130 is to outgo anti-peeping light. Even if the anti-peeping light-emitting element is formed on the sidewall of the anti-peeping opening 113, it has limited impact on the light outwent by the anti-peeping light-emitting element.

Considering that the light emitted from the light-emitting layer 132 on the sidewall of the anti-peeping opening 113 exits obliquely to the substrate 111, the component of the light perpendicular to the substrate 111 is relatively small. Therefore, the part of the emitted light does not require scattering by the second light scattering structure 162. Consequently, in the orthographic projection of the substrate 111, the second light scattering structure 162 does not overlap with the sidewall of the anti-peeping opening 113.

FIG. 9 is a schematic diagram of a second type of display panel according to the fourth embodiment of the present disclosure. As shown in FIG. 9, each of the plurality of anti-peeping sub-pixels 130 includes an anti-peeping light-emitting element, and each of the plurality of anti-peeping light-emitting elements includes a bottom electrode 131, a light-emitting layer 132, and a top electrode 133. The light-emitting layer 132 is disposed between the bottom electrode 131 and the top electrode 133, with the bottom electrode 131 positioned below the light-emitting layer 132. Each bottom electrode 131 is provided with a circular protrusion 131a, and the circular protrusion 131a is disposed in a middle region of the bottom electrode 131 and configured to diverge the anti-peeping light emitted by the corresponding anti-peeping light-emitting elements.

In the present embodiment, it is applicable to the solution where only the first light scattering structure 161 is provided. The reflection effect of the protrusion may alter the distribution of the emitted light from the anti-peeping light-emitting element, by arranging a protrusion on the bottom electrode 131 of the anti-peeping light-emitting element, when the light-emitting layer 132 emits light. This results in weaker light intensity in the vertical emission angle of the anti-peeping light-emitting element and stronger light intensity at a certain angle (relative to the normal direction of the substrate 111), thereby enhancing the anti-peeping light at the anti-peeping viewing angle and improving the anti-peeping effect.

Generally, the anti-peeping light-emitting element of each of plurality of the anti-peeping sub-pixels 130 and the light-emitting element of the display sub-pixel 120 may be driven by a pixel driving layer. Each display sub-pixel 120 may be individually driven and switched through a pixel active switch, while the anti-peeping sub-pixels 130 may be controlled in a unified manner. That is, the bottom electrodes 131 and the top electrodes 133 of multiple anti-peeping light-emitting elements are respectively connected for unified control.

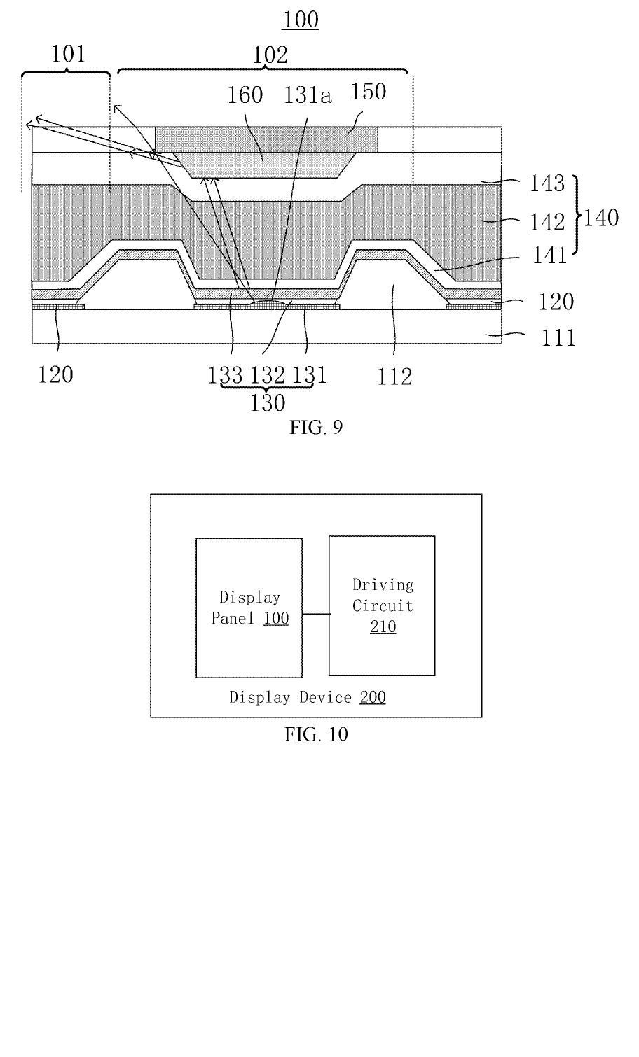

FIG. 10 is a schematic diagram of a display device according to the present disclosure. As shown in FIG. 10, the present disclosure further discloses a display device 200, which includes a driving circuit 210 and the display panel 100 according to any of the foregoing embodiments. The driving circuit 210 is configured to drive the display panel 100 to display images.

It should be noted that the inventive concept of the present disclosure may be formed into many embodiments, but limitations of the application document preclude exhaustive listing. Therefore, should no conflict be present, the various embodiments or technical features described above may be arbitrarily combined to form new embodiments. After the various embodiments or technical features are combined, the original technical effects may be enhanced.

The foregoing content describes the present disclosure in further detail in conjunction with specific optional embodiments, but it should not be construed that the specific implementation of the present disclosure is limited solely to these descriptions. For those of ordinary skill in the art to which the present disclosure pertains, several simple deductions or replacements may be made without departing from the inventive concept of the present disclosure, and these should all be regarded as falling within the protection scope of the present disclosure.

What is claimed is:

1. A display panel, comprising a plurality of opening areas and a non-opening area; wherein the display panel further comprises:
a substrate;
a pixel-defining layer, disposed on the substrate and located in the non-opening area;
a plurality of display sub-pixels, disposed in one-to-one correspondence with the plurality of opening areas respectively, and two adjacent display sub-pixels are separated by the pixel-defining layer;
a plurality of anti-peeping sub-pixels, disposed in the non-opening area, with at least one anti-peeping sub-pixel provided within a pixel, and each of the plurality of anti-peeping sub-pixels is separated from each of the plurality of display sub-pixels by the pixel-defining layer;
an encapsulation layer, disposed over the pixel-defining layer, the plurality of display sub-pixels, and the plurality of anti-peeping sub-pixels, and is configured to seal the display sub-pixels and the anti-peeping sub-pixels;
a plurality of light-shielding layers, disposed on the plurality of anti-peeping sub-pixels, and are arranged in one-to-one correspondence with the anti-peeping sub-pixels respectively, configured to block the light emitted perpendicularly to the substrate from the anti-peeping sub-pixels;and
a plurality of light-scattering structures, each of the plurality of light-scattering structures is disposed between each of the plurality of anti-peeping sub-pixels and each of the plurality of light-shielding layers, configured to scatter part of the anti-peeping light emitted from each of the plurality of anti-peeping sub-pixels to each of the plurality of light-shielding layers causing scattered light to be outwent from each of the plurality of opening areas.

2. The display panel according to claim 1, wherein an interior of each of the plurality of light-scattering structures is provided with light scattering particles, the light scattering particles comprise inorganic particles, organic particles, or composite particles;
the light scattering particles are configured to change a propagation direction of light, such that part of the anti-peeping light outwent from the anti-peeping sub-pixel toward the light-shielding layer is scattered and outwent through the opening area.

3. The display panel according to claim 2, wherein each of the plurality of light-scattering structures comprises a first light scattering structure, each first light scattering structure is disposed in direct contact with each of the plurality of light-shielding layers and disposed between each of the plurality of light-shielding layers and the encapsulation layer, under an orthogonal projection of the substrate, a projection of each first light scattering structure falls within a projection range of each of the plurality of light-shielding layers.

4. The display panel according to claim 3, wherein each of the plurality of first scattering structures has a cross-sectional shape of an inverted trapezoid, semicircle, semi-ellipse, triangle, or rectangle;
the encapsulation layer comprises a first inorganic layer, an organic layer, and a second inorganic layer, the first inorganic layer is disposed to cover the anti-peeping sub-pixels and display sub-pixels, and the organic layer is disposed between the first inorganic layer and the second inorganic layer, each first scattering structure is disposed between the first inorganic layer and each of the plurality of light-shielding layers;
wherein a thickness of each first scattering structure is greater than or equal to a thickness of the first inorganic layer and less than or equal to a thickness of the organic encapsulation layer.

5. The display panel according to claim 1, wherein the encapsulation layer comprises a first inorganic layer, an organic layer, and a second inorganic layer, the first inorganic layer is disposed to cover a plurality of anti-peeping sub-pixels and a plurality of display sub-pixels, and the organic layer is disposed between the first inorganic layer and the second inorganic layer;
each of the plurality of light-scattering structures further comprises a second light scattering structure, the second light scattering structure is disposed between the first inorganic layer and the organic layer;
in the orthographic projection of the substrate, each of the second light-scattering structures falls within the projection range of each of the plurality of light-shielding layers.

6. The display panel according to claim 5, wherein the pixel-defining layer is further provided with a plurality of anti-peeping openings configured to accommodate the anti-peeping sub-pixels, with each the anti-peeping sub-pixel disposed in one-to-one correspondence with each of the plurality of anti-peeping openings;
each of the second light-scattering structures is disposed within each of the plurality of anti-peeping openings;
wherein, in a case where each of the plurality of light scattering structure comprises a first scattering structure and a second light scattering structure, a width of each of the second light scattering structure is less than that of each of the first scattering structure; a region of the organic encapsulation layer corresponding to the anti-peeping sub-pixels is provided with a plurality of grooves, and each first scattering structure is correspondingly disposed within each of the plurality of grooves.

7. The display panel according to claim 6, wherein each of the plurality of anti-peeping sub-pixesls comprises an anti-peeping light-emitting element, a sidewall of each of the plurality of anti-peeping openings has a preset inclination angle to form an inclined surface, each anti-peeping light-emitting element extends from a bottom of the corresponding anti-peeping opening to a sidewall of the anti-peeping opening, the anti-peeping light outwent by each of the anti-peeping light-emitting elements in a region corresponding to the sidewall of each of the plurality of anti-peeping opening outgoes toward the plurality of opening areas corresponding to the anti-peeping light-emitting elements;
under the orthographic projection of the substrate, each of the second light-scattering structures is non-overlapping with the sidewall of each of the plurality of anti-peeping openings.

8. The display panel according to claim 2, wherein each of the plurality of anti-peeping sub-pixels comprises a anti-peeping light-emitting element, and each anti-peeping light-emitting element comprises a bottom electrode, a light-emitting layer, and a top electrode, the light-emitting layer is disposed between the bottom electrode and the top electrode, with the bottom electrode positioned below the light-emitting layer;
wherein each bottom electrode is provided with a circular protrusion, the circular protrusion is disposed in a middle region of each bottom electrode and configured to diverge the anti-peeping light emitted by the corresponding anti-peeping light-emitting elements.

9. The display panel according to claim 4, wherein the display panel further comprises a color filter layer, the color filter layer comprises a plurality of color filter portions and a plurality of light-transmitting portions, the plurality of color filter portions are disposed in one-to-one correspondence with the plurality of display sub-pixels, and the plurality of light-shielding layers and the plurality of light-transmitting portions are disposed on a same layer as the plurality of color filter portions;
a light-transmitting portion is disposed between each adjacent pair of the color filter portion and the light-shielding layer.

10. The display panel according to claim 3, wherein each of the first light-scattering structures is configured to diverge and emit the light outwent from each of the plurality of anti-peeping sub-pixels toward each of the plurality of light-shielding layers, so as to enhance the anti-peeping light at 25 degrees to 45 degrees from each of the plurality of anti-peeping sub-pixel.

11. The display panel according to claim 3, wherein, for each of the first light-scattering structures, a thickness in a direction perpendicular to the substrate is greater than a width in a direction parallel to the substrate, and a height of a surface of each of the first light-scattering structures proximate to each of the plurality of anti-peeping sub-pixels is lower than that of a surface of the pixel-defining layer proximate to each of the plurality of light-shielding layers.

12. The display panel according to claim 3, wherein the encapsulation layer comprises a first inorganic layer, an organic layer, and a second inorganic layer, the first inorganic layer is disposed to cover the anti-peeping sub-pixels and display sub-pixels, and the organic layer is disposed between the first inorganic layer and the second inorganic layer;
each of the plurality of light-scattering structures further comprises a second light scattering structure, the second light scattering structure is disposed between the first inorganic layer and the organic layer;
in the orthographic projection of the substrate, each of the second light-scattering structures falls within the projection range of each of the plurality of light-shielding layers.

13. The display panel according to claim 12, wherein, for each of the first ligh-scattering structures, a thickness in a direction perpendicular to the substrate is greater than a width in a direction parallel to the substrate, and a height of a surface of each of the first light-scattering structures proximate to each of the plurality of anti-peeping sub-pixels is lower than that of a surface of the pixel-defining layer proximate to each of the plurality of light-shielding layers.

14. A display device, comprising a driving circuit and a display panel, wherein the driving circuit is configured to drive the display panel to display; the display panel comprises a plurality of opening areas and a non-opening area; wherein the display panel further comprises:
a substrate;
a pixel-defining layer, disposed on the substrate and located in the non-opening area;
a plurality of display sub-pixels, disposed in one-to-one correspondence with the plurality of opening areas respectively, and two adjacent display sub-pixels are separated by the pixel-defining layer;
a plurality of anti-peeping sub-pixels, disposed in the non-opening area, with at least one anti-peeping sub-pixel provided within a pixel, and each of the plurality of anti-peeping sub-pixel is separated from each of the plurality of display sub-pixel by the pixel-defining layer;
an encapsulation layer, disposed over the pixel-defining layer, the plurality of display sub-pixels, and the plurality of anti-peeping sub-pixels, and is configured to seal the display sub-pixels and the anti-peeping sub-pixels;
a plurality of light-shielding layers, disposed on the plurality of anti-peeping sub-pixels, and are arranged in one-to-one correspondence with the anti-peeping sub-pixels respectively, configured to block the light emitted perpendicularly to the substrate from the anti-peeping sub-pixels;and
a plurality of light-scattering structures, each of the plurality of light-scattering structures is disposed between each of the plurality of anti-peeping sub-pixels and each of the plurality of light-shielding layers, configured to scatter part of the anti-peeping light emitted from each of the plurality of anti-peeping sub-pixels to each of the plurality of light-shielding layers, causing scattered light to be outwent from each of the opening areas.

15. The display panel according to claim 14, wherein an interior of each of the plurality of light-scattering structures is provided with light scattering particles, the light scattering particles comprise inorganic particles, organic particles, or composite particles;
the light scattering particles are configured to change a propagation direction of light, such that part of the anti-peeping light outwent from the anti-peeping sub-pixel toward the light-shielding layer is scattered and outwent through the opening area.

16. The display panel according to claim 15, wherein each of the plurality of light-scattering structures comprises a first light scattering structure, each of the first light scattering structures is disposed in direct contact with each of the plurality of light-shielding layers and disposed between each of the plurality of light-shielding layers and the encapsulation layer, under an orthogonal projection of the substrate, a projection of each first light scattering structure falls within a projection range of each of the plurality of light-shielding layers.

17. The display panel according to claim 16, wherein each of the plurality of first scattering structures has a cross-sectional shape of an inverted trapezoid, semicircle, semi-ellipse, triangle, or rectangle;
the encapsulation layer comprises a first inorganic layer, an organic layer, and a second inorganic layer, the first inorganic layer is disposed to cover the anti-peeping sub-pixels and display sub-pixels, and the organic layer is disposed between the first inorganic layer and the second inorganic layer, each first scattering structure is disposed between the first inorganic layer and each of the plurality of light-shielding layers;
wherein, a thickness of each first scattering structure is greater than or equal to the thickness of the first inorganic layer and less than or equal to a thickness of the organic encapsulation layer.
